(19) United States
(12) Patent Application Publication
(10) Pub. No.: US 2020/0359535 A1
(43) Pub. Date: Nov. 12, 2020

(54) CONTROL CIRCUIT FOR ESD CIRCUIT

(71) Applicant: MACRONIX INTERNATIONAL CO., LTD., Hsinchu (TW)

(72) Inventor: Shih-Yu WANG, Taipei City (TW)

(21) Appl. No.: 16/404,873

(22) Filed: May 7, 2019

(51) Int. Cl. H05K 9/00

(52) U.S. Cl. CPC H05K 9/0067

(57) ABSTRACT

Disclosed is a control circuit for ESD circuit, comprising a resistor unit and a voltage control unit, When the voltage of the first node of the ESD circuit is smaller than a threshold of the voltage control unit, the voltage control unit is turned off, a first voltage is output to the second node of the ESD circuit to keep the ESD circuit inactive; when the voltage of the first node of the ESD circuit is larger than or equals to the threshold of the voltage control unit, the voltage control unit is turned on, and a second voltage is output to the second node of the ESD circuit to cause the ESD circuit normally working,

### BACKGROUND OF THE INVENTION

### Field of the Invention

The invention relates to a control circuit, particularly to a control circuit for ESD circuit.

### Description of the Related Art

Electrical static discharge (ESD) event sometimes may occur in electronic devices. However, the glitches generated from ESD ESD event may damage the components in the electronic devices. Therefore, to avoid damage to the components in the electronic devices by ESD event, ESD (protection) circuits may be configured in the electronic device to provide a safe discharging path for the current generated from ESD event.

### SUMMARY OF THE INVENTION

An embodiment of the present invention discloses a control circuit for ESD circuit, comprising a resistor unit and a voltage control unit. The resistor unit comprises a first node and a second node. The first node of the resistor unit is coupled to a first node of an ESD circuit. The second node of the resistor unit is coupled to a second node of the ESD circuit. The voltage control unit comprises a first node and a second node. The first node of the voltage control circuit is coupled to the second node of the resistor unit and the second node of the ESD circuit. The second node of the voltage control circuit is coupled to a reference voltage, When the voltage of the first node of the ESD circuit is smaller than a threshold of the voltage control unit, the voltage control unit is turned off, a first voltage is configured as a control signal to be output to the second node of the ESD circuit to keep the ESD circuit inactive; when the voltage of the first node of the ESD circuit is larger than or equals to the threshold of the voltage control unit, the voltage control unit is turned on, and a second voltage is configured as the control signal to be output to the second node of the ESD circuit to cause the ESD circuit normally working.

Another embodiment of the present invention discloses a control circuit for ESD circuit, comprising a resistor unit, a voltage control unit, an inverter unit and an output unit. The resistor unit comprises a first node and a second node. The first node of the resistor unit is coupled to a first node of an ESD circuit. The voltage control unit comprises a first node and a second node. The first node of the voltage control circuit is coupled to the second node of the resistor unit. The second node of the voltage control circuit is coupled to a reference voltage. The inverter unit comprises a first node, a second node, a third node and a fourth node, The first node of the inverter unit is coupled to the second node of the resistor unit. The third node of the inverter unit is coupled to the first node of the ESD circuit. The fourth node of the inverter unit is coupled to the reference voltage. The output unit comprises a first node, a second node and a third node. The first node of the output unit is coupled to the second node of the inverter unit. The second node of the output unit is coupled to the first node of the ESD circuit or the reference voltage. The third node of the output unit coupled to a second node of the ESD circuit. When the voltage of the first node of the ESD circuit is smaller than a threshold of the voltage control unit, the voltage control unit is turned off, the output unit is turned on, and a first voltage is configured as a control signal to be output to the second node of the ESD circuit to keep the ESD circuit inactive; when the voltage of the first node of the ESD circuit is larger than or equals to the threshold of the voltage control unit, the voltage control unit is turned on, the output unit is turned off to cause the ESD circuit normally working.

Yet another embodiment of the present invention discloses a control circuit for ESD circuit, comprising a resistor unit and a voltage control unit. The resistor unit comprises a first node and a second node. The second node of the resistor unit is coupled to a reference voltage. The voltage control unit comprises a first node and a second node. The first node of the voltage control circuit is coupled to a first node of an ESD circuit. The second node of the voltage control circuit is coupled to the first node of the resistor unit and a second node of the ESD circuit. When the voltage of the first node of the ESD circuit is smaller than a threshold of the voltage control unit, the voltage control unit is turned off, a first voltage is configured as a control signal to be output to the second node of the ESD circuit to keep the ESD circuit inactive; when the voltage of the first node of the ESD circuit is larger than or equals to the threshold of the voltage control unit, the voltage control unit is turned on, and a second voltage is configured as the control signal to be output to the second node of the ESD circuit to cause the ESD circuit normally working.

Yet another embodiment of the present invention discloses a control circuit for ESD circuit, comprising a resistor unit, a voltage control unit, an inverter unit and an output unit. The resistor unit comprises a first node and a second node. The second node of the resistor unit is coupled to a reference voltage. The voltage control unit comprises a first node and a second node. The first node of the voltage control circuit is coupled to a first node of an ESD circuit. The second node of the voltage control circuit is coupled to the first node of the resistor unit. The inverter unit comprises a first node, a second node, a third node and a fourth node. The first node of the inverter unit is coupled to the first node of the resistor unit and the second node of the voltage control unit. The third node of the inverter unit is coupled to the first node of the ESD circuit. The fourth node of the inverter unit is coupled to the reference voltage. The output unit comprises a first node, a second node and a third node. The first node of the output unit is coupled to the second node of the inverter unit. The second node of the output unit is coupled to the first node of the ESD circuit or the reference voltage. The third node of the output unit is coupled to a second node of the ESD circuit. When the voltage of the first node of the ESD circuit is smaller than a threshold of the voltage control unit, the voltage control unit is turned off, the output unit is turned on, and a first voltage is configured as a control signal to be output to the second node of the ESD circuit to keep the ESD circuit inactive; when the voltage of the first node of the ESD circuit is larger than or equals to the threshold of the voltage control unit, the voltage control unit is turned on, the output unit is turned off to cause the ESD circuit normally working.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 shows a block diagram of an ESD circuit.

FIG. 2 shows a block diagram of a control circuit according to an embodiment of the present invention.

FIG. 3 shows a block diagram of a control circuit according to another embodiment of the present invention.

FIG. 4 shows a block diagram of a control circuit according to yet another embodiment of the present invention.

FIG. 5 shows a block diagram of a control circuit according to yet another embodiment of the present invention.

FIG. 6 shows a block diagram of a control circuit according to yet another embodiment of the present invention.

FIG. 7 shows a block diagram of a control circuit according to yet another embodiment of the present invention.

### DETAILED DESCRIPTION OF THE INVENTION

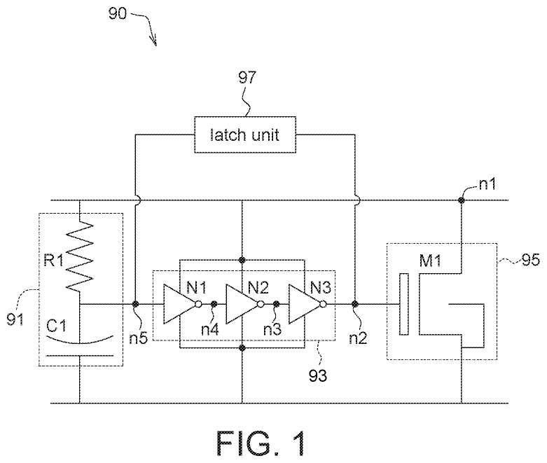

Referring to FIG. 1, FIG. 1 shows a block diagram of an ESD circuit. The ESD circuit 90 may be configured in an electronic device, for example, a memory device, for protecting the components in the electronic device from damaging by ESD. The ESD circuit includes a resistor-capacitor (RC) unit 91, a driving unit 93, a switch unit 95 and a latch unit 97. The RC unit 91 may include a resistor R1 and a capacitor C1 Wherein the resistor R1 and the capacitor C1 are serial connected. The driving unit 93 may include a number of inverter N1-N3 which are serial connected. The switch unit 95 may include a transistor M1, wherein the transistor M1 is a NMOS in this example. The latch unit 95 may be implemented by several ways, for example, by transistors and/or inverters. A first node of the driving unit 93 is coupled to a second node of the RC unit 91. A second node of the driving circuit 93 is coupled to a second node of the switch unit 95. A first node of the latch unit 97 is coupled to a first node of the driving unit 93. A second node of the latch unit 97 is coupled to the second node of the driving unit 93. A first node of the switch unit 95 is coupled to a first node of the RC unit 91. A third node of the switch unit 95 is coupled to a third node of the RC unit 91. When an ESD event occurs and a glitch is generated on the node n1, the voltage of the node n5 may become a low voltage level, the voltage of the node n4 may become a high voltage level, the voltage of the node n3 may become a low voltage level, the voltage of the node n2 may become a high voltage level, so that the switch unit 95 may be turned on and let the current of the glitch may be flow out via the switch unit 95. While ESD event occurs, the latch unit 97 may lock the voltage of the node n5 to a state of low voltage level according to the voltage of the node n2 to keep the switch unit 95 on for at least a time constant of RC unit 91. However, while other noise (e.g., not due to an ESD event, and the current/voltage of other noise may be lower that may not affect normal operation of the electronic device) occurs on the node n1, the ESD circuit 90 may wrongly determine that an ESD event occurs, and the switch unit 95 may be turned on. Thus, the switch unit 95 which should not be turned on becomes a leakage current path. The latch unit 97 locks the voltage of the node n5 to keep switch unit 95 on, and the current leaks continuously via the switch unit 95. The problem described above may affect the power consumption of the electronic device, that is, the power consumption of the electronic device may increase is accordingly. To solve the problem, the present invention provides a control circuit used for controlling ESD circuit. The control circuit may send a control signal to release the state of current leaking of the ESD circuit while the ESD circuit works incorrectly due to noise, and the control circuit may not affect the normal operation of the ESD circuit while an ESD event occurs.

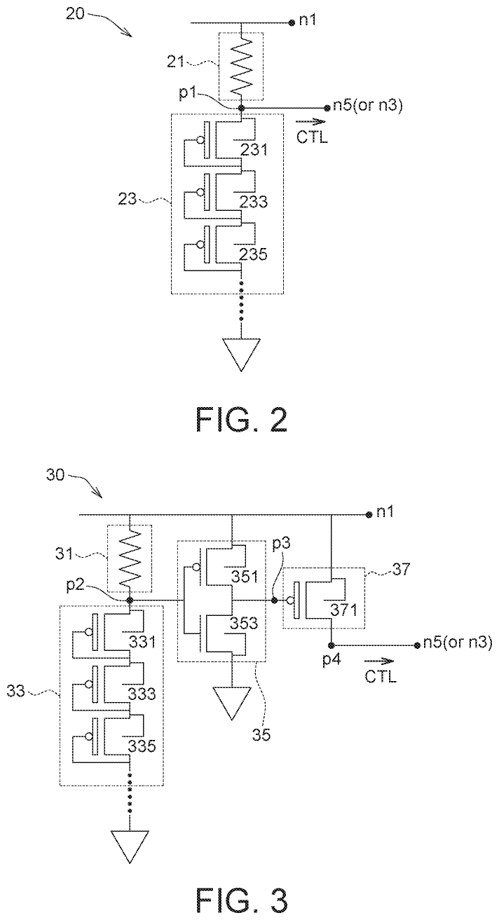

Referring to FIG. 2, FIG. 2 shows a block diagram of a control circuit for ESD circuit according to an embodiment of the present invention. The control circuit 20 includes a resistor unit 21 and a voltage control unit 23. A first node of the resistor unit 21 is coupled to the node n1 of ESD circuit 90. A second node of the resistor unit 21 is coupled to the node n5 of the ESD circuit 90 and a first node of the voltage control unit 23, A second node of the voltage control unit 23 is coupled to a reference voltage (e.g., ground). The voltage control unit 23 may include may include a number of transistors 231˜233, wherein the transistors 231˜233 are serial connected, each of the transistors 231˜233 is a PMOS transistor, and each of the transistors 231˜233 is diode-connected (that is, the gate of each transistor is coupled to its own drain) which means that each of the transistors 231˜233 is equivalent to a diode. Next, the working principle of the control circuit 20 is illustrated. Assuming that a turn on voltage of each of the transistors 231˜233 is respectively Vd1, Vd2, Vd3. When the voltage of the node n1 is smaller than a threshold Vt (wherein Vt=Vd1+Vd2+Vd3), the voltage of the node n1 may not be able to turn on all the transistors 231˜233, so that the voltage of the node p1 may be substantially the same as or close to the voltage of the node n1. In this case, the control signal CTL output from the node p1 to the node n5 may keep the voltage of the node n5 substantially the same as or close to the voltage of the node n1, so that the switch unit 95 may be kept off to prevent from current leaking. When the voltage of the node n1 is larger than or equals to the threshold Vt, the control unit 23 may be turned on, and the voltage of the node p1 may be pulled down to a voltage lower than the voltage of the node n1. In this case, the control signal CTL output from the node p1 to the node n5 may cause the voltage of the node n5 lower than the voltage of node n1, so that the switch unit 95 may be turned on.

In short, the case that the voltage of the node n1 is lower than the threshold Vt is considered as a case that the ESD event does not occur, that is, the switch unit 95 of the ESD circuit 90 does not need to be turned on; in the contrary, the case that the voltage of the node n1 is larger than of equals to the threshold Vt is considered as a case that the ESD event occurs, that is, the switch unit 95 of the ESD circuit 90 needs to be turned on to let the ESD current can be eliminated. With configuring the number of the transistors serial connected in the voltage control unit 23, the value of the threshold Vt may be determined. In other words, while the voltage of the noise on the node n1 is smaller than the threshold Vt, or the voltage of the noise on the node n1 is larger than or equals to the threshold Vt which turns the switch unit 95 incorrectly and the voltage of the node n1 drops to smaller than the threshold after the noise gone, the control circuit 20 may send control signal CTL to the ESD circuit 90 to disable the ESD circuit 90 for preventing from current leaking. While the ESD event occurs, the control circuit 20 may not affect the normal operation of the ESD circuit, and the ESD current may be eliminated.

Noted that, in another embodiment, the node p1 may be coupled to the node n3 rather than the node n5.

Referring to FIG. 3, FIG. 3 shows a block diagram of a control circuit for ESD circuit according to another embodiment of the present invention. The control circuit 30 includes a resistor unit 31, a voltage control unit 33, an inverter unit 35 and an output unit 37. A first node of the resistor unit 31 is coupled to the node n1 of the ESD circuit 90, A second node of the resistor unit 31 is coupled to a first node of the voltage control unit 33 and a first node of the inverter unit 35. A second node of the voltage control unit 33 is coupled to a reference voltage (e,g., ground). A second node of the inverter unit 35 is coupled to a first node of the output unit 37. A third node of the inverter unit 35 is coupled to the node n1 of the ESD circuit 90 and the first node of the resistor unit 31. A fourth node of the inverter unit 35 is coupled to the reference voltage (e.g., ground). A second node of the output unit 37 is coupled to the node n1 of the ESD circuit 90 and the first node of the resistor unit 31. A third node of the output unit 37 is coupled to the node n5 (or node n3) of the ESD circuit 90. The circuit structure of the voltage control unit 33 is similar to the voltage control unit 23, and may not be illustrated repeatedly. The inverter unit 35 may include a PMOS transistor 351 and a NMOS transistor 353, wherein the PMTS transistor 351 and the NMOS transistor 353 may be connected by a well-known way to form an inverter, The output unit 37 may include a PMTS transistor 371, which has a gate configured as the first node of the output unit 37, a source configured as the second node of the output unit 37, and a drain configured as the third node of the output unit 37.

Next, the working principle of the control circuit 30 is illustrated. Assuming a turn on voltage of each of the transistors 331˜333 is respectively Vd1′, Vd2′, Vd3′. When the voltage of the node n1 is smaller than a threshold Vt′ (wherein Vt′=Vd1′+Vd2′+Vd3′), the voltage of the node n1 may not be able to turn on all the transistors 331˜333, and the voltage of the node p2 may be substantially the same as or close to the voltage of the node n1. Thus, the PMOS transistor 351 of the inverter unit 35 may be turned off, and the NMOS transistor 353 may be turned on. The voltage of the node p3 may be pulled down to the reference voltage (e.g., ground voltage). The output unit 37 (i.e., the PMOS transistor 371) may be turned on. In this case, the control signal CTL output from the node p4 to the node n5 (or n3) may keep the voltage of the node n5 (or n3) substantially the same as or close to the voltage of the node n1, so that the switch unit 95 may be kept off to prevent from current leaking. When the voltage of the node n1 is larger than or equals to the threshold Vt′, the control unit 33 may be turned on, and the voltage of the node p2 may be pulled down to be lower than the voltage of node n1 (e.g., close to the reference voltage). The PMOS transistor 351 of the inverter unit 35 may be turned on, and the NMOS transistor 353 may be turned off. The voltage of the node p3 may be pulled up to be substantially the same as or close to the voltage of the node n1. The output unit 37 (i.e., the PMOS transistor 371) may be turned off. In this case, there may be no control signal CTL being output to the node n5, and the switch unit 95 may be turned on due to the ESD event.

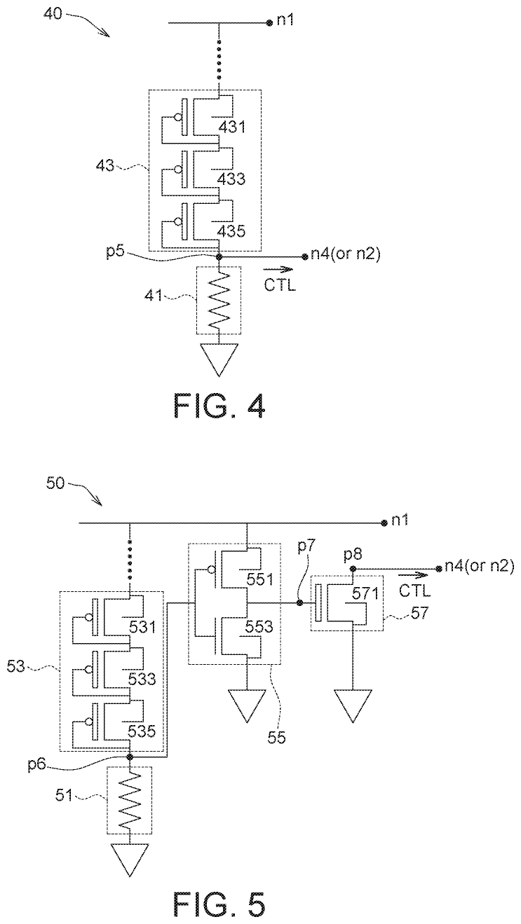

Referring to FIG. 4, FIG. 4 shows a block diagram of a control circuit for ESD circuit according to yet another embodiment of the present invention. The control circuit 40 includes a resistor unit 41 and a voltage control unit 43. A first node of the voltage control unit 43 is coupled to the node n1 of the ESD circuit 90. A first node of the resistor unit 41 is coupled to a second node of the voltage control unit 43 and the node n4 (or node n2) of the ESD circuit 90. A second node of the resistor unit 41 is coupled to a reference voltage (e.g., ground). The circuit structure of the voltage control unit 43 is similar to the voltage control unit 23, and may not be illustrated repeatedly.

Next, the working principle of the control circuit 40 is illustrated. Assuming a turn on voltage of each of the transistors 431˜433 is Vd1″, Vd2″, Vd3″. When the voltage of the node n1 is smaller than a threshold Vt″ (wherein Vt″=Vd1″+Vd2″+Vd3′), the voltage of the node n1 may not be able to turn on all the transistors 431˜433, thus the voltage of the node p5 may be substantially the same as or close to the reference voltage. In this case, the control signal CTL output from the node p5 to the node n4 (or node n2) may keep the voltage of the node n4 (or node n2) substantially the same as or close to the reference voltage. The switch unit 95 may be kept off to prevent from current leaking, When the voltage of the node n1 is larger than or equals to the threshold Vt″, the voltage control unit 43 may be turned on, and the voltage of the node p5 may be pulled up to be close to the voltage of the node n1. In this case, the control signal CTL output from the node p5 to the node n4 (or node n2) may keep the voltage of the node n4 (or node n2) substantially the same as or close to the voltage of the node n1, and the switch unit 95 may be turned on.

Referring to FIG. 5, FIG. 5 shows a block diagram of a control circuit for ESD circuit according to yet another embodiment of the present invention. The control circuit 50 includes a resistor unit 51, a voltage control unit 53, an inverter unit 55 and an output unit 57. In this embodiment, the connection between the resistor unit 51 and the voltage control unit 53 is similar to the embodiment shown in FIG. 4. The connection of the inverter unit 55 is similar to the embodiment shown in FIG. 3, the difference is that a first node of the inverter unit 55 is coupled to a first node of the resistor unit 51 and a second node of the voltage control unit 53. The output unit 57 includes a NMOS transistor 571, wherein a gate of the NMOS transistor 571 is configured as a first node of the output unit 57 to be coupled to a second node of the inverter unit 55, a drain of the NMOS transistor 571 is configured as a second node of the output unit 57 to be coupled to the reference voltage (e.g., ground), and a source of the NMOS transistor 571 is configured as a third node of the output unit 57 to be coupled to the node n4 or the node n2 of the ESD circuit 90.

Next, the working principle of the control circuit 50 is illustrated. When he voltage of the node n1 is smaller than a threshold of the voltage control unit 53, the voltage of the node n1 may not be able to turn on the voltage control unit 53, thus the voltage of the node p6 may be substantially the same as or close to the reference voltage. The PMOS transistor 551 of the inverter unit 55 may be turned on, the NMOS transistor 353 may be turned off, and the voltage of the node p7 may be pulled up to be substantially the same as or close to the voltage of the node n1. The output unit 57 (i.e., the NMOS transistor 571) may be turned on, and the voltage of the node p8 may be pulled down to be substantially the same as or close to the reference voltage. In this case, the reference voltage may be configured as the control signal CTL output from the node p8 to the node n4 (or n2), so that the switch unit 95 may be turned off. When the voltage of the node n1 is larger than of equals to the threshold of the voltage control unit 53, the voltage control unit 53 may be turned on. The voltage of the node p6 may be pulled up to be close to the voltage of the node n1. The PMOS transistor 551 of the inverter unit 55 may be turned off, the NMOS transistor 553 may be turned on, and the voltage of the node p7 may be pulled down to be substantially the same as or close to the reference voltage. The output unit 57 the NMOS transistor 571) may be turned off. In this case, there may be no control signal CTL being output from the node p8 to the node n4 (or node n2) of the ESD circuit 90.

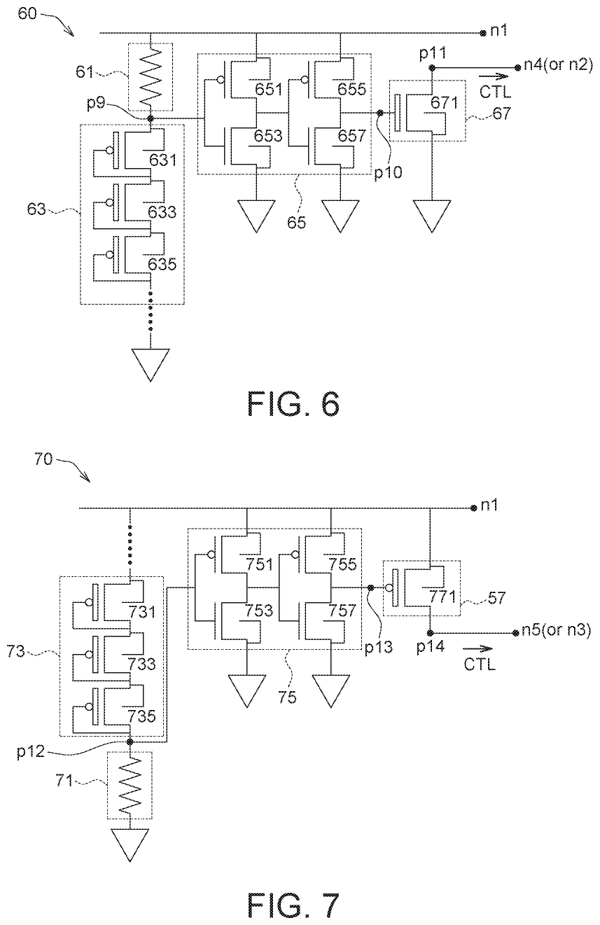

Referring to FIG. 6, FIG. 6 shows a block diagram of a control circuit for ESD circuit according to yet another embodiment of the present invention. The control circuit 60 includes a resistor unit 61, a voltage control unit 63, an inverter unit 65 and an output unit 67. In this embodiment, the connection between the resistor unit 61 and the voltage control unit 63 is similar to the embodiment shown in FIG. 2. The inverter unit 65 includes a first inverter and a second inverter. The first inverter includes a PMOS transistor 651 and a NMOS transistor 653. The second inverter includes a PMOS transistor 655 and a NMOS transistor 657. The connection between the inverter unit 65 and the resistor unit 61, voltage control unit 63 is similar to the embodiment shown in FIG. 3. The output unit 67 includes a NMOS transistor 671, wherein a gate of the NMOS transistor 671 is configured as a first node of the output unit 67 to be coupled to a second node of the inverter unit 65, a drain of the NMOS transistor 671 is configured as a second node of the output unit 67 to be coupled to the reference voltage (e.g., ground), and a source of the NMOS transistor 671 is configured as a third node of the output unit 67 to be coupled to the node n4 or the node n2 of the ESD circuit 90.

Next, the working principle of the control circuit 60 is illustrated. When the voltage of the node n1 is smaller than a threshold of the voltage control unit 63, the voltage of the node n1 may not be able to turn of the voltage control unit 63, thus the voltage of the node p9 may be substantially the same as or close to the voltage of the node n1. The PMOS transistor 651 of the inverter unit 65 may be turned off, the NMOS transistor 653 may be turned on, the PMOS transistor 655 may be turned on, and the NMOS transistor 657 may be turned off. The voltage of the node p10 may be pulled up to be substantially the same as or close to the voltage of the node n1. The output unit 67 (i.e., the NMOS transistor 671) may be turned on, and the voltage of the node p11 may be pulled down to be substantially the same as or close to the reference voltage. In this case, the reference voltage is configured as the control signal CTL to be output from the node p11 to the node n4 (or n2). The switch unit 95 may be turned off. When the voltage of the node n1 is larger than or equals to the threshold of the voltage control unit 63, the voltage control unit 63 may be turned on, thus the voltage of the node p9 may be pulled down to be close to the reference voltage. The PMOS transistor 651 of the Inverter unit 65 may be turned on, the NMOS transistor 653 may be turned off, the PMOS transistor 655 may be turned off, and the NMOS transistor 657 may be turned on. The voltage of the node p10 may be pulled down to be substantially the same as or close to the reference voltage. The output unit 67 (i.e., the NMOS transistor 671) may be turned off. In this case, there may be no control signal CTL being output from the node p11 to the node n4 (or node n2) of the ESD circuit 90.

Referring to FIG. 6, FIG. 6 shows a block diagram of a control circuit for ESD circuit according to yet another embodiment of the present invention. The control circuit 70 includes a resistor unit 71, a voltage control unit 73, an inverter unit 75 and an output unit 77. In this embodiment, the connection between the resistor unit 71 and the voltage control unit 73 is similar to the embodiment shown in FIG. 4. The inverter unit 75 includes a first inverter and a second inverter. The first inverter includes a PMOS transistor 751 and a NMOS transistor 753. The second inverter includes a PMOS transistor 755 and a NMOS transistor 757. The connection between the inverter unit 75 and the resistor unit 71, voltage control unit 73 is similar to the embodiment shown in FIG. 5. The output unit 77 includes a PMOS transistor 771, wherein a gate of the PMOS transistor 771 is configured as a first node of the output unit 77 to be coupled to a second node of the inverter unit 75, a source of the PMOS transistor 771 is configured as a second node of the output unit 77 to be coupled to the node n1 of the ESD circuit 90 and a first node of the voltage control unit 71, and a drain of the PMOS transistor 771 is configured as a third node of the output unit 77 to be coupled to the node n5 or n3 of the ESD circuit 90.

Next, the working principle of the control circuit 70 is illustrated. When the voltage of the node n1 is smaller than a threshold of the voltage control unit 73, the voltage of the node n1 may not be able to turn on the voltage control unit 73, thus the voltage of the node p12 may be substantially the same as or close to the reference voltage. The PMOS transistor 751 of the inverter unit 75 may be turned on, the NMOS transistor 753 may be turned off, the PMOS transistor 755 may be turned off, the NMOS transistor 757 may be turned on, and the voltage of the node p13 may be pulled down to be substantially the same as or close to the reference voltage. The output unit 77 (i.e., the PMOS transistor 771) may be turned on. The voltage of the node p14 may be pulled up to be substantially the same as or close to the voltage of the node n1. In this case, the voltage of the node n1 may be configured as the control signal CTL to be output from the node p14 to the node n5 (or n3), and the switch unit 95 may be turned off. When the voltage of the node n1 is larger than or equals to the threshold of the voltage control unit 73, the voltage control unit 73 may be turned on, thus the voltage of the node p12 may be pulled up to be close to the voltage of the node n1. The PMOS transistor 751 of the inverter unit 75 may be turned off, NMOS transistor 753 may be turned on, the PMOS transistor 755 may be turned on, the NMOS transistor 757 may be turned off, and the voltage of the node p13 may be pulled up to be substantially the same as or close to the voltage of the node n1. The output unit 77 (i.e., the PMOS transistor 771) may be turned off. In this case, there may be no control signal CTL being output from the node p14 to the node n5 (or node n3) of the ESD circuit 90.

The above embodiments are merely for purpose of illustration. In other embodiments, the resistor unit may be implemented by transistor(s) or parasitic resistor(s); the voltage control unit may be implemented by serial connecting one or more diodes or by serial connecting one or more diode-connected NMOS transistors; the threshold of the voltage control unit may be configured (determined) by the quantity of diodes or transistors being serial connected; the inverter unit may include one or more inverters, and the quantity of the inverters may be configured according to the current requirement for driving the output unit.

When the ESD circuit should not work, particularly, when the ESD event does not occur but other noise occurs, the control circuit provided by the present invention may send a control signal to keep the ESD circuit in a state of inactivity for preventing from current leaking. When the ESD event occurs, that is, the ESD circuit should work, the control circuit may not affect the normal operation of the ESD circuit, and the ESD current may be eliminated.

While the invention has been described by way of example and in terms of the preferred embodiment (s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A control circuit for ESD circuit, comprising:
a resistor unit, comprising a first node and a second node, the first node of the resistor unit coupled to a first node of an ESD circuit, the second node of the resistor unit coupled to a second node of the ESD circuit; and
a voltage control unit, comprising a first node and a second node, the first node of the voltage control circuit coupled to the second node of the resistor unit and the second node of the ESD circuit, the second node of the voltage control circuit coupled to a reference voltage,
wherein when the voltage of the first node of the ESD circuit is smaller than a threshold of the voltage control unit, the voltage control unit is turned off, a first voltage is configured as a control signal to be output to the second node of the ESD circuit to keep the ESD circuit inactive; when the voltage of the first node of the ESD circuit is larger than or equals to the threshold of the voltage control unit, the voltage control unit is turned on, and a second voltage is configured as the control signal to be output to the second node of the ESD circuit to cause the ESD circuit normally working.

2. The control circuit according to claim 1, wherein, wherein the voltage control unit comprises one or more transistors, the one or more transistors are serial connected, and each of the one or more transistors is diode-connected.

3. A control circuit for ESD circuit, comprising:
a resistor unit, comprising a first node and a second node, the first node of the resistor unit coupled to a first node of an ESD circuit;
a voltage control unit, comprising a first node and a second node, the first node of the voltage control circuit coupled to the second node of the resistor unit, the second node of the voltage control circuit coupled to a reference voltage,
an inverter unit, comprising a first node, a second node, a third node and a fourth node, the first node of the inverter unit coupled to the second node of the resistor unit, the third node of the inverter unit coupled to the first node of the ESD circuit, and the fourth node of the inverter unit coupled to the reference voltage; and
an output unit, comprising a first node, a second node and a third node, the first node of the output unit coupled to the second node of the inverter unit, the second node of the output unit coupled to the first node of the ESD circuit or the reference voltage, and the third node of the output unit coupled to a second node of the ESD circuit,
wherein when the voltage of the first node of the ESD circuit is smaller than a threshold of the voltage control unit, the voltage control unit is turned off, the output unit is turned on, and a first voltage is configured as a control signal to be output to the second node of the ESD circuit to keep the ESD circuit inactive; when the voltage of the first node of the ESD circuit is larger than or equals to the threshold of the voltage control unit, the voltage control unit is turned on, the output unit is turned off to cause the ESD circuit normally working.

4. The control circuit according to claim 3, wherein, wherein the voltage control unit comprises one or more transistors, the one or more transistors are serial connected, and each of the one or more transistors is diode-connected.

5. The control circuit according to claim 3, wherein, wherein the inverter unit comprises one or more inverters.

6. A control circuit for ESD circuit, comprising:
a resistor unit, comprising a first node and a second node, the second node of the resistor unit coupled to a reference voltage; and
a voltage control unit, comprising a first node and a second node, the first node of the voltage control circuit coupled to a first node of an ESD circuit, the second node of the voltage control circuit coupled to the first node of the resistor unit and a second node of the ESD circuit,
wherein when the voltage of the first node of the ESD circuit is smaller than a threshold of the voltage control unit, the voltage control unit is turned off, a first voltage is configured as a control signal to be output to the second node of the ESD circuit to keep the ESD circuit inactive; when the voltage of the first node of the ESD circuit is larger than or equals to the threshold of the voltage control unit, the voltage control unit is turned on, and a second voltage is configured as the control signal to be output to the second node of the ESD circuit to cause the ESD circuit normally working.

7. The control circuit according to claim 6, wherein, wherein the voltage control unit comprises one or more transistors, the one or more transistors are serial connected, and each of the one or more transistors is diode-connected.

8. A control circuit for ESD circuit, comprising:
a resistor unit, comprising a first node and a second node, the second node of the resistor unit coupled to a reference voltage;
a voltage control unit, comprising a first node and a second node, the first node of the voltage control circuit coupled to a first node of an ESD circuit, the second node of the voltage control circuit coupled to the first node of the resistor unit,
an inverter unit, comprising a first node, a second node, a third node and a fourth node, the first node of the inverter unit coupled to the first node of the resistor unit and the second node of the voltage control unit, the third node of the inverter unit coupled to the first node of the ESD circuit, and the fourth node of the inverter unit coupled to the reference voltage; and
an output unit, comprising a first node, a second node and a third node, the first node of the output unit coupled to the second node of the inverter unit, the second node of the output unit coupled to the first node of the ESD circuit or the reference voltage, and the third node of the output unit coupled to a second node of the ESD circuit,
wherein when the voltage of the first node of the ESD circuit is smaller than a threshold of the voltage control unit, the voltage control unit is turned off, the output unit is turned on, and a first voltage is configured as a control signal to be output to the second node of the ESD circuit to keep the ESD circuit inactive; when the voltage of the first node of the ESD circuit is larger than or equals to the threshold of the voltage control unit, the voltage control unit is turned on, the output unit is turned off to cause the ESD circuit normally working.

9. The control circuit according to claim 8, wherein, wherein the voltage control unit comprises one or more transistors, the one or more transistors are serial connected, and each of the one or more transistors is diode-connected.

10. The control circuit according to claim 8, wherein, wherein the inverter unit comprises one or more inverters.
